(19) United States
(12) Patent Application Publication
(10) Pub. No.: US 2011/0056228 A1
(43) Pub. Date: Mar. 10, 2011

(54) COOLING APPARATUS FOR NUCLEAR MAGNETIC RESONANCE IMAGING RF COIL

(76) Inventors: Jyh-Horng CHEN, Taipei (TW); In-Tsang Lin, Taipei (TW)

(21) Appl. No.: 12/879,655

(22) Filed: Sep. 10, 2010

(30) Foreign Application Priority Data
Sep. 10, 2009 (TW) 098130477

(51) Int. Cl. F25D 31/00; G01R 33/44

(52) U.S. Cl. 62/259.2; 324/318

(57) ABSTRACT

The present invention discloses a cooling apparatus for Nuclear Magnetic Resonance Imaging (NMRI) RF coils comprising a base, a cup, an input tube and an output tube. The input tube and the output tube are connected to the cup, in which the base and the cup are tightly sucked together to form a vacuum space by the vacuum caused by the negative pressure when the air is drawn out. The vacuum is able to block the conduction of low temperature. The base, the cup, the input tube and the output tube may be made of heat-isolation materials with high strength of hardness. The main objective of the present invention is to provide a low temperature system for long time use by the protection of a vacuum space; therefore the particular RF coil is used to retrieve NMRI signals. By reducing the resistance, the noise is therefore restrained, and the signal-to-noise ratio is enhanced to achieve high resolution and the scanning time is significantly reduced.

### BACKGROUND OF THE INVENTION

1. Field of the Invention

The present invention relates to a cooling apparatus for a Nuclear Magnetic Resonance Imaging (NMRI) RF coils. More particularly, the present invention relates to a cooling apparatus which is designed for long time use by a protection of a vacuum space.

2. Descriptions of the Related Art

1. 2-D Magnetic Resonance Imaging Principle:

The NMRI or magnetic resonance imaging (MRI) technology is a significant imaging tool being used for clinical diagnosis recently.

The NMRI technology applies a strong magnetic field to align the most of hydrogen atoms inside human body in the major magnetic field direction. Then the instrument generates pulses to change the rotation alignment direction of the hydrogen atoms inside human body, and then the atomic nucleuses release the absorbed energy and generate electric-magnetic signals. The computer then analysis the signals and compose images, which are the so-called MRI images.

Similarly, the water molecules of human contain a plurality of hydrogen atomic nucleuses. Those hydrogen atomic nucleuses are magnetic. The NMRI scanning is about putting the human within a strong and uniform static magnetic field first, and then exciting the hydrogen atomic nucleuses of human by a particular RF radio pulse.

The MRI system comprises a magnet system and a RF system. The magnet system comprises a major magnetic field being configured to generate the highly-uniform magnetic field, a gradient being configured to generate and control the gradient of the magnetic field for realizing the spatial codes of the NMR signals. The system comprises three coils for generating the gradients in x, y, and x directions. By adding the magnetic fields of the coils, it is able to derive a gradient in arbitrary direction.

The RF system comprises a RF emitter, which is configured to generate a short and strong RF field for been applied onto the sample in pulse form. Then the hydrogen atomic nucleus in the sample presents nuclear magnetic resonance (NMR) phenomenon. The RF system still comprises a RF receiver, which is configured to receive the NMR signals and amplify the NMR signals then pass the signals to the image process system.

2. Related Technologies

The RF coil is configured to be the emitting and receiving device in a magnetic resonance imaging system, the quality of the RF coil is highly related to the image quality and the accuracy of the reconstruction result. Some conventional technologies apply Polystyrene as a container in a gradient. Formula among the Nuclear Magnetic Resonance SNR (Signal-to-Noise Ratio), the RF coil temperature, the RF coil resistance, the subject temperature, and the resistance is denoted as follow (Hoult and Richards [1])

$$SNR ∝ \frac{{B}_{1}^{xy} ( r )}{\sqrt{{T}_{c} {R}_{c} + {T}_{s} {R}_{s}}}$$

According to the conventional documents [2]-[6], it is known that the SNR of NRMI can be efficiently reduced by lowing the RF coil temperature and the resistance. However, most of the conventional documents apply hi-density Polystyrene as the low temperature device for the advantages of easy design and obtainment thereof. The Polystyrene is able to storage the liquid nitrogen as the cooling material, however, after a certain time, the external surface of the Polystyrene would present frosting and the subject would be frozen. Thus the inventor brings up the novel low temperature device for long time use.

The conventional technologies relate to the present invention are described as follows:

1. High-Tc superconducting receiving coils for nuclear magnetic resonance imaging [7] The experimental design takes the Polystyrene case as the low temperature device for the advantages of easy design and obtainment thereof. The Polystyrene is able to storage the liquid nitrogen as the cooling material, however, after a certain time, the external surface of the Polystyrene would present frosting and the subject would be frozen. The adapted coil system comprises three coils of a HTS receiving coil, a signal retrieving coil, and a frequency adjustment coil. The HTS receiving coil is fixed and the relative positions of the signal retrieving coil and the frequency adjustment are changeable in forward and backward direction. Thus, the adjustable range of frequency is limited, and the operation is complex. Meanwhile, the Q value is not high enough, thus the maximum energy cannot be fine tuned and ensured due to the resident image part of the resistance, and the energy is wasted.

2. The U.S. Pat. No. 5,258,710, Cryogenic probe for NMR microscopy [8], applies a low temperature liquid for lowing the coil temperature. The HTS film is directly immersed. A sample in small size is put in a tube and nitrogen is driven therein for warming the sample and keeping it from frozen. The retrieving coil is an inductive coil for retrieving signal. In signal transmission mode, the RF signal is induced by the retrieving signal coil and makes the HTS film transmit signal to the sample. In signal receiving mode, the signal from the sample is received, and then the inductive coil is used for generating image. The HTS film is damaged due to been directly immersed. Although the temperature drops very fast, but the sample can be only placed in the tube, and the size of the coil is 18 mm, thus only the small sample can be made. Besides, the design of the patent comprises a plurality of complex cavities, which is not easy for fabrication.

3. The U.S. Pat. No. 7,003,963, Cooling of receive coil in MRI scanners [9], provides a low temperature device been adapted by a France lab, which comprises a cooling machine in front end for lowing temperature. The middle portion is configured to place a subject for delivering temperature. It applies indirect cooling way to make the HTS film reach a critical temperature. The US patent designs two vacuum rooms and is disadvantaged in a long lowing temperature time up to four hours and a hi-value sapphire is needed for delivering temperature in the middle portion. Meanwhile, the low temperature device can only place a film in 12 mm size.

4. Two Theses Provided by France Lab:

(a) Development, manufacture and installation of a cryo-cooled HTS coil system for high-resolution in-vivo imaging of the mouse at 1.5 T, Methods [10]

(b) Performance of a Miniature High-Temperature Superconducting (HTS) Surface Coil for In Vivo Microimaging of the Mouse in a Standard 1.5 T Clinical Whole-Body Scanner [11]

The two theses are advantaged in protecting the sample from been frozen and the sample is not immersed in the liquid nitrogen for protecting the HTS film. The theses take coil system comprising a HTS coil, a matching coil, and a frequency adjustment coil. The device applies a complex way to retrieve signals by adjusting relative positions of the three coils. The device is disadvantaged in that it takes four hours to reach the critical temperature. For now, all low temperature system cannot reach the critical temperature efficiently; also, the present systems have complex structure. Thus, a novel cooling apparatus for a NMRI RF coil is provided.

### SUMMARY OF THE INVENTION

The primary objective of the present invention is to provide a low temperature system that applies a vacuum space for long time use and a particular RF coil for retrieving NMRI signals. The present invention may reduce the resistance to restrain the noise and enhance the SNR, thus hi-resolution is achieved and the scanning time can be significantly decreased.

Another objective of the present invention is to provide a cooling apparatus for a NMRI RF coil that is made of heat-isolation material. The major advantage of the heat-isolation material is that it can be formed one-piece, thus the vacuum space can be formed inside for protecting the HTS coil.

Another objective of the present invention is to provide a cooling apparatus for a Nuclear Magnetic Resonance Imaging RF coil. The cooling apparatus can be applied for different HTS RF coils such as surface coil, body coil, birdcage coil, and array coil.

Still another objective of the present invention is to provide a cooling apparatus for a Nuclear Magnetic Resonance Imaging RF coil. The coil cooling system comprises a liquid or a gas cooling recycle device, or storage device, pressure bumper, and transmission tubes for cooling the coupled coil.

To achieve the aforementioned objectives, the present invention comprises a base, a cup, an input tube and an output tube. The input tube and the output tube are connected to the cup, in which the base and the cup are tightly sucked together to form a vacuum space by the vacuum caused by the negative pressure when the air is drawn out. The vacuum is able to block the conduction of low temperature. The base, the cup, the input tube and the output tube may be made of heat-isolation materials with high hardness.

### BRIEF DESCRIPTION OF THE DRAWINGS

FIG. 1 is a 3-D diagram of the solar-infrared-rays sensing garden lamp of the present invention;

Please refer to the following figures for the detail of this better practice invention for the technology and purpose. The figures include the follows:

FIG. 1 illustrates the system diagram of the cooling apparatus of a NMRI RF coil of the present invention and a NMRI system;

FIG. 2A illustrates a 3D diagram of the cooling apparatus of a NMRI RF coil of the present invention;

FIG. 2B illustrates a 3D cross-sectional diagram of the cooling apparatus of a NMRI RF coil of the present invention;

FIG. 3 illustrates a cross-sectional diagram of the vacuum input tube of the cooling apparatus of a NMRI RF coil of the present invention; and

FIG. 4 illustrates a cross-sectional diagram of the vacuum output tube of the cooling apparatus of a NMRI RF coil of the present invention

### DESCRIPTION OF THE PREFERRED EMBODIMENT

To easily express the aforementioned objectives, features, and advantages of the present invention, better embodiments are described hereinafter jointly with the figures.

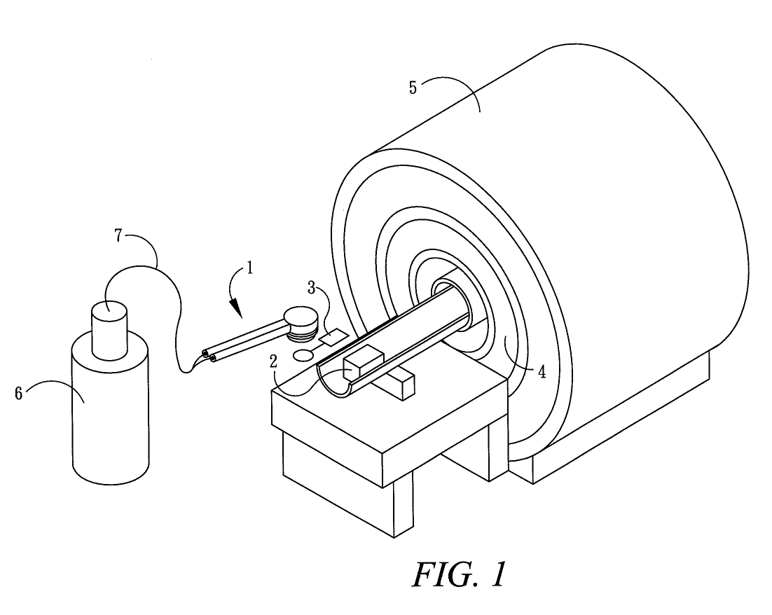

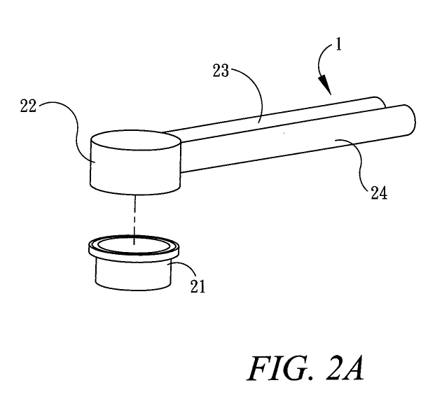

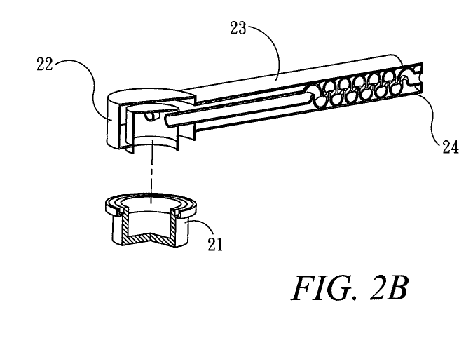

First, refer to FIGS. 1, 2, which illustrate the principle of two-dimensional (2D) MRI procedure as follows. As a subject 2 to determine is placed in a static magnetic field 5, a region of the subject 2 can be excited by using a RF coil 3, giving signals with respect to all the excitation and relaxation of nucleus excitations and relaxations in the region. With a (magnetic field) gradient applied, the RF coil 3 can receive those signals, which can be processed to MR image. If the change in the structure or functionality of the region is to be realized, the gradient may be adjusted so that slices can be acquired from various locations in the region. The RF coil 3 needs to keep hi-speed signal transmission, thus the RF coil 3 needs to keep within HTS temperature. In general conductors, the electrons run through the atom and interact with the lattice formed by the atoms, and portion of energy then pass to the lattice and cause lattice vibration, which causes energy loss and forms resistance. In a metallic conductor, the interaction between the lattice and the conductive electrons increases as well as the temperature increases. Therefore the resistance increases as well as the temperature increases. When the temperature increases above the critical temperature, the superconductor presents features just like a general conductor or semiconductor with resistance. However, when the temperature decreases below the critical temperature, the electrons can move freely without influence of the lattice, thus the resistance presents zero now, and the resistance is so-called “zero resistance”. That is why the temperature is so-called critical temperature. The magnetic field goes along with the electric field, when the temperature of the superconductor is below the critical temperature, the internal magnetic field is now excluded and the superconductor presents a zero-magnetic field status, also realized as anti-magnetic. To efficiently use the zero-resistance and anti-magnetic features, the cooling apparatus 1 of a NMRI RF coil of the present invention is configured to cool the RF coil 3 below the critical temperature of the RF coil 3.

When the temperature of the conductor is below the critical temperature, the magnetic field inside the superconductor is excluded and the superconductor presents a zero-magnetic status, also called anti-magnetic. To efficiently use the features of zero-resistance and anti-magnetic, the objective of the cooling apparatus 1 of a NMRI RF coil of the present invention is to decrease the temperature of the RF coil 3 to be below the critical temperature of the RF coil 3.

Refer to FIGS. 2A, 2B, which illustrate the embodiment of the cooling apparatus of a NMRI RF coil of the present invention. The cooling apparatus of a NMRI RF coil of the present invention comprises a base 21, a cup 22, an input tube 23, and an output tube 24. The input tube 23 and the output tube 24 are connected to the cup 22. The base 21 and the cup 22 are tightly sucked together to form a vacuum space by the vacuum caused by the negative pressure when the air is drawn out. The vacuum is able to block the conduction of low temperature. The base 21, the cup 22, the input tube 23 and the output tube 24 may be made of heat-isolation materials with high hardness, such as hi-hardness glass fiber, glass, and quartz glass.

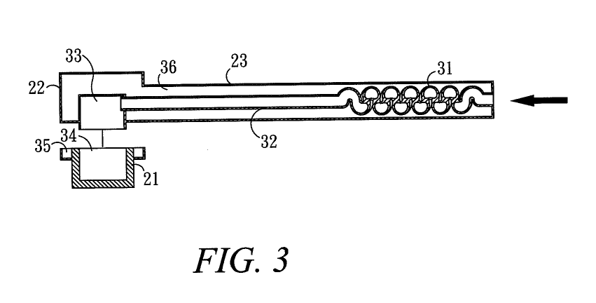

Refer to FIGS. 1 and 3, which illustrate the cross-sectional diagrams of the cooling apparatus of a NMRI RF coil of the present invention. The input tube 23 comprises a liquid nitrogen spiral input tube 31 and an input connection tube 32, and a vacuum space 36 is formed between the input tube 23, the liquid nitrogen spiral input tube 31, and the input connection tube 32. The present invention applies the vacuum for heat-isolation, which is so-called pure vacuum heat-isolation. It requires an air-pressure below 1.33m Pa in the heat-isolation space to keep the vacuity, therefore the air convection and most of the resident air conduction are blocked and good heat-isolation, fast temperature drop and recovery are ensured. The low temperature channel and container with two-wall mezzanine to keep hi-vacuum are so-called a Dewer. In this kind of heat-isolation structure, the major leaking heat in the low temperature area is radiant heat, and the next is small amount of resident air convection and solid structure heat conduction.

The liquid nitrogen is driven into an input terminal of the liquid nitrogen spiral input tube 31 from the liquid nitrogen storage device 6 through a channel 7, and the liquid nitrogen flows through the other end of the liquid nitrogen spiral input tube 31 then goes into the input connection tube 32. The cup 22 is set with a concave 33, and the input connection tube 32 is connected to the concave 33 of the cup 22. The liquid nitrogen flows through the input connection tube 32 to the concave 33 of the cup 22. The liquid nitrogen spiral input tube 31 is formed spiral for enlarging the water-heat exchange area of the liquid nitrogen spiral input tube 31, therefore the temperature increase of the liquid nitrogen is speeded-up and the liquid nitrogen is able to be transmitted to the concave 33 of the cup 22 fast.

The base 21 is set with a concave 34, and the base 21 and the cup 22 are configured to be jointly used with O-Ring by vacuum-pumping, the base 21 is set with the concave 34 jointly forming a temporary liquid nitrogen storage space with the concave 34 of the cup 22. The O-Ring can be placed in the ring-shape groove 35, and the space in the groove 35 is configured to be a vacuum to combine the base 21 and the cup 22. The liquid nitrogen is transmitted from the input connection tube 32 to the temporary liquid nitrogen storage space formed by the concaves 33, 34 of the base 21 and the cup 22. A coil is placed to touch the bottom of the base 21 or in the bottom of the base 21. The just aforementioned coil can be a HTS RF coil, such as a surface coil, a body coil, a birdcage coil, or an array coil. When the coil is operated in hi-speed, it generates hi-temperature. When a subject presents different temperatures in different portions, heat conduction generates, and the heat runs from the portion with higher temperature to the portion with lower temperature. Since the temperature is different form the internal surface to the external surface of the isolation material, the coil operated in hi-speed passes heat to the liquid nitrogen temporarily stored in the concaves 33, 34 of the base 21 and the cup 22 by heat conduction for heat dissipation.

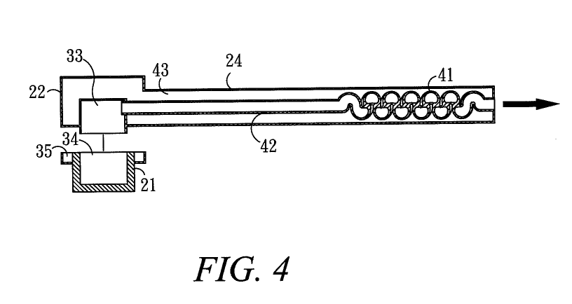

Please Refer to FIGS. 1 and 4, which illustrate the liquid nitrogen channel after absorbing the heat. The liquid nitrogen is delivered to outside via the output tube 24 after absorbing the heat. A vacuum space 43 is formed among the vacuum output tube 24 and the liquid nitrogen spiral output tube 41, the output connection tube 42. One end of the output connection tube 42 is connected to the concave 33 of the cup 22, and the other end of the output connection tube 42 is connected to the liquid nitrogen spiral output tube 41. The liquid nitrogen flows into the liquid nitrogen spiral output tube 41 via the output connection tube 42 after absorbing heat, then the liquid nitrogen flows into the liquid nitrogen storage device 6. The liquid nitrogen storage device 6 is set with a waste material storage tank for storing the used liquid nitrogen. The liquid nitrogen storage device may be set with recycle device for recycling and reusing the used liquid nitrogen.

The cooling apparatus for a Nuclear Magnetic Resonance Imaging RF coil provided in this invention has the following benefits comparing to other conventional practices:

1. The present invention applies the liquid nitrogen for cooling the RF coil. By reducing the resistance, the noise is therefore restrained, and the signal-to-noise ratio is enhanced to achieve high resolution and the scanning time is significantly reduced.

2. The present invention is designed with a vacuum space inside for protecting the HTS coil.

3. The cooling apparatus for a Nuclear Magnetic Resonance Imaging RF coil of the present invention can be applied for different HTS RF coils such as surface coil, body coil, birdcage coil, and array coil.

The present invention conforms to the patentability and an application is filed in light of the law. The aforementioned descriptions are solely for explaining the embodiments of the present invention and are not intended to limit the scope of the present invention. Any equivalent practice of modification within the spirit of the present invention should be treated as being within the scope of patent of the present invention.

### REFERENCES

[1] D. I. Hoult and R. E. Richards, “The signal-to-noise ratio of the nuclear magnetic resonance experiment,” J. Magn. Reson., vol. 24, pp. 71-85, 1976.
[2] R. D. Black, T. A. Early, P. B. Roemer, O. M. Mueller, A. Mogro-Campero, L. G. Turner, and G. A. Johnson, “A high-temperature superconducting receiver for nuclear magnetic resonance microscopy,” Science, vol. 259, pp. 793-5, 1993.
[3] J. R. Miller, S. E. Hurlston, Q. Y. Ma, D. W. Face, D. J. Kountz, J. R. MacFall, L. W. Hedlund, and G A. Johnson, “Performance of a high-temperature superconducting probe for in vivo microscopy at 2.0 T,” Magn Reson Med, vol. 41, pp. 72-9, January 1999
[4] G Grasso, A. Malagoli, N. Scati, P. Guasconi, S. Roncallo, and A. S. Siri, “Radio frequency response of Ag-sheathed (Bi, Pb)(2)Sr2Ca2Cu3O10+x superconducting tapes,” Superconductor Science & Technology, vol. 13, pp. L15-L18, October 2000.
[5] J. Yuan and G X. Shen, “Quality factor of Bi(2223) high-temperature superconductor tape coils at radio frequency,” Superconductor Science & Technology, vol. 17, pp. 333-336, March 2004.
[6] M. C. Cheng, B. P. Yan, K. H. Lee, Q. Y. Ma, and E. S. Yang, “A high temperature superconductor tape RF receiver coil for a low field magnetic resonance-imaging system,” Superconductor Science & Technology, vol. 18, pp. 1100-1105, August 2005.
[7] Hsu-Lei Lee, In-Tsang Lin, Jyh-Horng Chen, Herng-Er Horng, and Hong-Chang Yang, High-Tc superconducting receiving coils for nuclear magnetic resonance imaging, Applied Superconductivity Conference, Jacksonville, Fla., ETATS-UNIS 2004.
[8] U.S. Pat. No. 5,258,710, Cryogenic probe for NMR microscopy.
[9] U.S. Pat. No. 7,003,963, Cooling of receive coil in MRI scanners.
[10] Jean-Christophe Ginefri, Marie Poirier-Quinot, Olivier Girard, Luc Darrasse, Technical aspects: Development, manufacture and installation of a cryo-cooled HTS coil system for high-resolution in-vivo imaging of the mouse at 1.5 T, Methods (San Diego, Calif.) 2007; 43(1): 54-67.
[11] Marie Poirier-Quinot, Jean-Christophe Ginefri, Olivier Girard, Philippe Robert, and Luc Darrasse, Performance of a Miniature High-Temperature Superconducting (HTS) Surface Coil for In Vivo Microimaging of the Mouse in a Standard 1.5 T Clinical Whole-Body Scanner, Magnetic resonance in medicine: official journal of the Society of Magnetic Resonance in Medicine/Society of Magnetic Resonance in Medicine 2008; 60(4): 917-27.

What is claimed is:

1. A cooling apparatus for a Nuclear Magnetic Resonance Imaging RF coil, comprising:
a vacuum input tube, which is configured to transmit liquid nitrogen from one end of the vacuum input tube to the other end of the vacuum input tube;
a vacuum cup, being connected to the vacuum input tube;
a vacuum base, being placed on the vacuum cup; and
a vacuum output tube, being connected to the vacuum cup.

2. The cooling apparatus for a Nuclear Magnetic Resonance Imaging RF coil as claimed in claim 1, wherein the vacuum input tube comprises a liquid nitrogen spiral input tube and an input connection tube, and a vacuum space is formed between the vacuum input tube, the liquid nitrogen spiral input tube, and the input connection tube, and the liquid nitrogen is driven into an input terminal of the liquid nitrogen spiral input tube from the liquid nitrogen storage device through a channel, and the liquid nitrogen flows through the other end of the liquid nitrogen spiral input tube then goes into the input connection tube.

3. The cooling apparatus for a Nuclear Magnetic Resonance Imaging RF coil as claimed in claim 2, wherein the vacuum cup is set with a concave being connected to the input connection tube of the vacuum input tube for transmitting the liquid nitrogen from the input connection tube to the concave of the vacuum cup.

4. The cooling apparatus for a Nuclear Magnetic Resonance Imaging RF coil as claimed in claim 3, wherein the vacuum base is set with a concave jointly forming a temporary liquid nitrogen storage space with the concave of the vacuum cup, and the liquid nitrogen is transmitted from the input connection tube of the vacuum input tube to the temporary liquid nitrogen storage space formed by the concaves of the vacuum base and the vacuum cup, and a coil is placed to touch the bottom of the vacuum base or in the bottom of the vacuum base.

5. The cooling apparatus for a Nuclear Magnetic Resonance Imaging RF coil as claimed in claim 3, wherein the vacuum output tube comprises a liquid nitrogen spiral output tube and an output connection tube, and a vacuum space is formed between the vacuum output tube, the liquid nitrogen spiral output tube, and the output connection tube, and one end of the output connection tube is connected to the concave of the vacuum cup, the other end of the output connection tube is connected to the liquid nitrogen spiral output tube, the liquid nitrogen that has absorbed heat energy flows through the output connection tube and into the liquid nitrogen spiral output tube and then out to a liquid nitrogen storage device.

6. The cooling apparatus for a Nuclear Magnetic Resonance Imaging RF coil as claimed in claim 1, wherein the vacuum base is set with a concave jointly forming a temporary liquid nitrogen storage space with the edge of the concave of the vacuum cup, and the liquid nitrogen is transmitted from the input connection tube of the vacuum input tube to the temporary liquid nitrogen storage space formed by the concaves of the vacuum base and the vacuum cup, and a coil is placed to touch the bottom of the vacuum base or in the bottom of the vacuum base.

7. The cooling apparatus for a Nuclear Magnetic Resonance Imaging RE coil as claimed in claim 1, wherein the coil is a surface coil.

8. The cooling apparatus for a Nuclear Magnetic Resonance Imaging RF coil as claimed in claim 1, wherein the coil is a body coil.

9. The cooling apparatus for a Nuclear Magnetic Resonance Imaging RF coil as claimed in claim 1, wherein the coil is a birdcage coil.

10. The cooling apparatus for a Nuclear Magnetic Resonance Imaging RF coil as claimed in claim 1, wherein the coil is an array coil.

11. The cooling apparatus for a Nuclear Magnetic Resonance Imaging RF coil as claimed in claim 1, wherein the vacuum base, the vacuum cup, the vacuum input tube, and the vacuum output tube are made of heat-isolation materials.

12. The cooling apparatus for a Nuclear Magnetic Resonance Imaging RF coil as claimed in claim 11, wherein the heat-isolation material is a hi-hardness quartz glass.

13. The cooling apparatus for a Nuclear Magnetic Resonance Imaging RF coil as claimed in claim 11, wherein the heat-isolation material is a glass fiber.

14. The cooling apparatus for a Nuclear Magnetic Resonance Imaging RF coil as claimed in claim 11, wherein the heat-isolation material is a glass.

15. The cooling apparatus for a Nuclear Magnetic Resonance Imaging RF coil as claimed in claim 1, wherein the coil is a cooling RF coil.

16. The cooling apparatus for a Nuclear Magnetic Resonance Imaging RF coil as claimed in claim 1, wherein the coil is a cooling hi-temperature superconductor (HTS) RF coil.
